(19) United States
(12) Patent Application Publication
(10) Pub. No.: US 2022/0384379 A1
(43) Pub. Date: Dec. 1, 2022

(54) SEMICONDUCTOR DEVICE

(71) Applicant: SONY SEMICONDUCTOR SOLUTIONS CORPORATION, KANAGAWA (JP)

(72) Inventors: TAKESHI YOSHIDA, KANAGAWA (JP); TSUTOMU NISHIDE, KANAGAWA (JP); KAZUMI KOBAYASHI, KANAGAWA (JP); YOSHIHIKO TOYOSHIMA, KANAGAWA (JP); SUSUMU KOSHINAMI, KUMAMOTO (JP)

(21) Appl. No.: 17/765,184

(22) PCT Filed: Sep. 30, 2020
(86) PCT No.: PCT/JP2020/037122

§ 371 Date: Mar. 30, 2022

(30) Foreign Application Priority Data
Oct. 10, 2019 (JP) 2019-187122

(51) Int. Cl. H01L 23/00; H01L 27/146

(52) U.S. Cl. CPC H01L 24/29; H01L 27/14601; H01L 24/32; H01L 24/30; H01L 2224/29012; H01L 2224/30146; H01L 2224/2902; H01L 2224/32221

(57) ABSTRACT

A semiconductor device (1) according to the present disclosure includes a semiconductor chip (2), an interposer substrate (3), and a die-bonding material (4) formed in a partially opened annular shape in a plan view. The semiconductor chip (2) includes a region in which an integration density of an electronic circuit is high (23, 24, and 25) and a region in which the integration density is low (22). The semiconductor chip (2) is implemented on the interposer substrate (3). The die-bonding material (4) formed in a partially opened annular shape in a plan view is provided between the region in which the integration density is high (23, 24, and 25) in the semiconductor chip (2) and the interposer substrate (3).

### FIELD

The present disclosure relates to a semiconductor device.

### BACKGROUND

There is a semiconductor device including a semiconductor chip mounted on a substrate via a die-bonding material (for example, refer to Patent Literature 1).

### CITATION LIST

### Patent Literature

Patent Literature 1: JP 2019-114681 A

### SUMMARY

### Technical Problem

However, in the semiconductor device, the heat dissipation performance may be lowered due to the arrangement of the die-bonding material. Therefore, the present disclosure proposes a semiconductor device that can improve the heat dissipation performance.

### Solution to Problem

According to the present disclosure, a semiconductor device is provided. The semiconductor device includes a semiconductor chip, a substrate, and a die-bonding material formed in a partially opened annular shape in a plan view. The semiconductor chip includes a region in which an integration density of an electronic circuit is high and a region in which the integration density is low. The semiconductor chip is implemented on the substrate. The die-bonding material formed in a partially opened annular shape in a plan view is provided between the region in which the integration density is high in the semiconductor chip and the substrate.

### BRIEF DESCRIPTION OF DRAWINGS

FIG. 1 is an explanatory view of a semiconductor device according to the present disclosure in a plan view.

FIG. 2A is an explanatory view illustrating a cross-sectional structure of the semiconductor device according to the present disclosure.

FIG. 2B is an exploded perspective view of the semiconductor device according to the present disclosure.

FIG. 3A is an explanatory view illustrating a cross-sectional structure of a semiconductor device according to a modification example of the present disclosure.

FIG. 3B is an exploded perspective view of the semiconductor device according to the modification example of the present disclosure.

FIG. 4 is an explanatory view illustrating an arrangement example of a high density region and a die-bonding material in the semiconductor device according to the present disclosure.

FIG. 5 is an explanatory view illustrating an arrangement example of a high density region and a die-bonding material in the semiconductor device according to the present disclosure.

FIG. 6 is an explanatory view illustrating an arrangement example of a high density region and a die-bonding material in the semiconductor device according to the present disclosure.

FIG. 7 is an explanatory view illustrating an arrangement example of a high density region and a die-bonding material in the semiconductor device according to the present disclosure.

FIG. 8 is an explanatory view illustrating an arrangement example of a high density region and a die-bonding material in the semiconductor device according to the present disclosure.

### DESCRIPTION OF EMBODIMENTS

Hereinbelow, embodiments of the present disclosure will be described in detail with reference to the drawings. Note that, in each of the following embodiments, identical components are labeled with the same reference signs, and duplicate description is omitted.

[1. Configuration of Semiconductor Device in Plan View]

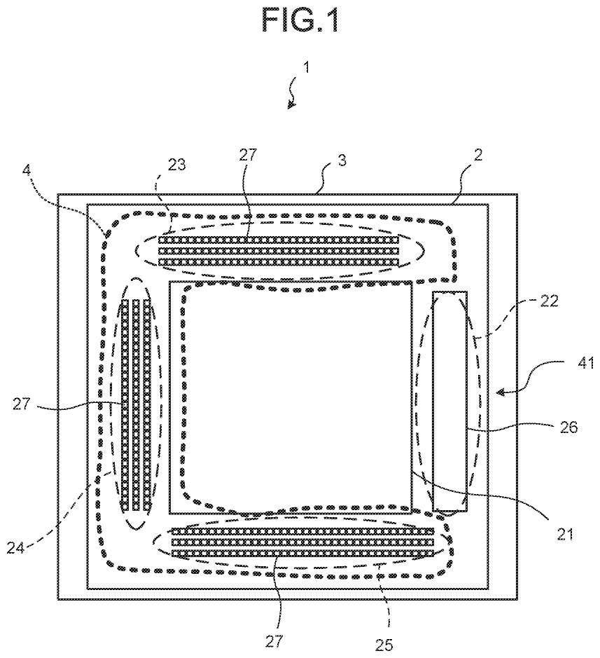

FIG. 1 is an explanatory view of a semiconductor device 1 according to the present disclosure in a plan view. As illustrated in FIG. 1, a semiconductor device 1 includes a semiconductor chip 2, an interposer substrate 3 on which the semiconductor chip 2 is implemented, and a die-bonding material 4 formed in a partially opened annular shape in a plan view. Note that the interposer substrate 3 may be any substrate as long as it is a substrate on which the semiconductor chip 2 is implemented.

Also, since the die-bonding material 4 is an adhesive resin provided between the interposer substrate 3 and the semiconductor chip 2 in order to secure the semiconductor chip 2 to the interposer substrate 3, the die-bonding material 4 is indicated by a thick dotted line in FIG. 1.

Hereinbelow, a case where the semiconductor chip 2 is an image sensor will be described, but the semiconductor chip 2 is not limited to the image sensor, and may be any electronic device. The semiconductor chip 2 includes at the center in a plan view an image capturing region 21 in which a plurality of image capturing pixels are two-dimensionally arranged.

The semiconductor chip 2 also includes around the image capturing region 21 a region in which the integration density of electronic circuits is low (hereinbelow, the region is referred to as a “low density region 22”) and regions in which the integration densities of electronic circuits are high (hereinbelow, the regions are referred to as “high density regions 23, 24, and 25”).

In the low density region 22, a peripheral circuit 26 including, for example, a vertical scan (VS) circuit, a digital to analog converter (DAC), a vertical monitor (VM) circuit, a bias current (BC) circuit, and a charge pump (CP) circuit, is provided.

In the high density regions 23, 24, and 25, peripheral circuits 27 including, for example, a static random access memory (SRAM), a load mos (LM) transistor, a comparator (CM), and a counter (CN), are provided. Since the peripheral circuit 26 provided in the low density region 22 has a relatively low integration density, the peripheral circuit 26 is less likely to be at a high temperature even when operated.

On the other hand, since the peripheral circuits 27 provided in the high density regions 23, 24, and 25 have high integration densities, the peripheral circuits 27 generate heat and are at high temperatures when operated. In the image sensor, when the high density regions 23, 24, and 25 become at high temperatures, whitening called thermal shading occurs in a portion of a captured image captured by image capturing pixels located in the vicinity of the high density regions 23, 24, and 25, and the image quality is lowered.

The die-bonding material 4 of the semiconductor device 1 is provided between the high density regions 23, 24, and 25 in the semiconductor chip 2 and the interposer substrate 3, and is formed in a partially opened annular shape in a plan view. Therefore, the die-bonding material 4 functions as a heat dissipation member that efficiently absorbs and dissipates heat generated from the high density regions 23, 24, and 25. Accordingly, the semiconductor device 1 can improve the heat dissipation performance.

Also, in the semiconductor chip 2, the high density regions 23, 24, and 25 are provided along sides (three sides out of the four sides in the example illustrated in FIG. 1) excluding at least one side which is the low density region 22 among the four sides serving as the outer edge. The die-bonding material 4 is provided along the high density regions 23, 24, and 25 in the semiconductor chip 2, and includes, in a portion between the low density region 22 and the interposer substrate 3, an open portion 41 that opens a part of the annular shape in a plan view.

As a result, the semiconductor chip 2 can effectively release heat dissipated from the high density regions 23, 24, and 25 in the peripheral edge portion to the center region in a plan view provided with the image capturing region 21, through the open portion 41 provided in the die-bonding material 4 formed in an annular shape in a plan view to the outside of the semiconductor chip 2. Accordingly, the semiconductor chip 2 including the image sensor can suppress the occurrence of thermal shading.

In addition, as described above, the low density region 22 is less likely to be at a high temperature while the high density regions 23, 24, and 25 are at high temperatures. Therefore, in the semiconductor chip 2, a temperature gradient is generated from the high density regions 23, 24, and 25 toward the low density region 22. As a result, the semiconductor device 1 can efficiently release heat generated from the high density regions 23, 24, and 25 to the outside of the semiconductor chip 2 through the open portion 41 provided in the low density region 22.

[2. Structure of Semiconductor Device]

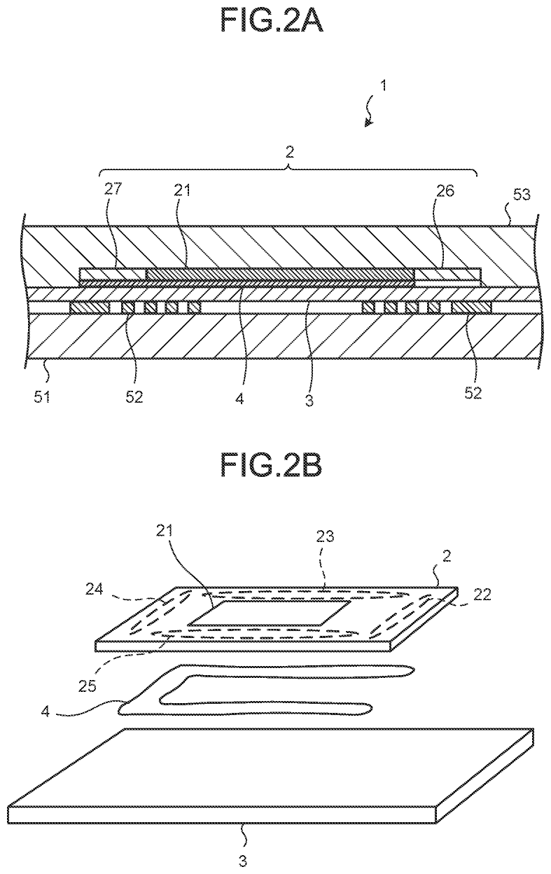

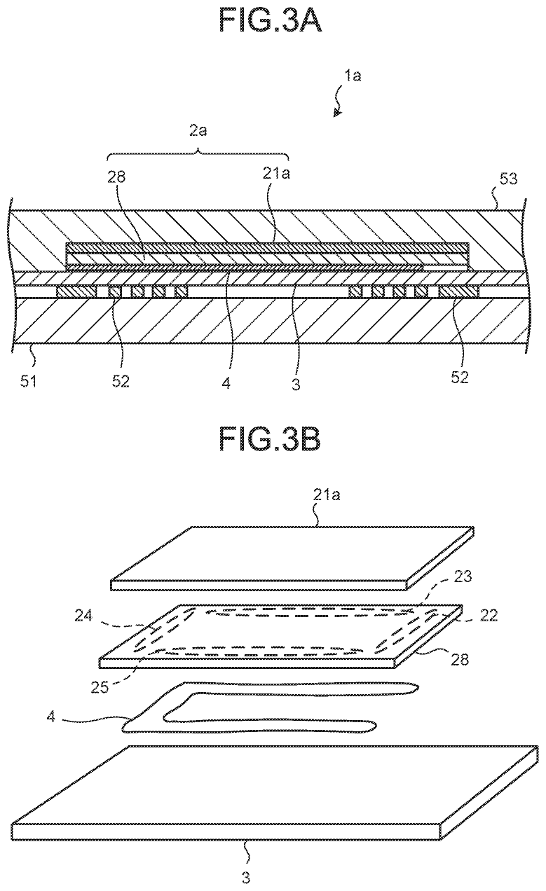

Next, a structure of the semiconductor device 1 will be described with reference to FIGS. 2A and 3B. FIG. 2A is an explanatory view illustrating a cross-sectional structure of the semiconductor device according to the present disclosure. FIG. 2B is an exploded perspective view of the semiconductor device according to the present disclosure.

As illustrated in FIG. 2A, the semiconductor device 1 includes the interposer substrate 3 provided on a substrate 51 via bumps 52, the semiconductor chip 2 provided on the interposer substrate 3 via the die-bonding material 4, and a frame 53 provided so as to surround the semiconductor chip 2.

The semiconductor chip 2 includes the image capturing region 21 at the center, and the peripheral circuits 26 and 27 and the like around the image capturing region 21. As illustrated in FIG. 2B, the semiconductor chip 2 includes the image capturing region 21 in a region surrounded by the high density regions 23, 24, and 25 and the low density region 22.

The die-bonding material 4 is provided immediately below the high density regions 23, 24, and 25 along the high density regions 23, 24, and 25, which are at high temperatures. The die-bonding material 4 absorbs heat generated from the high density regions 23, 24, and 25 from the lower side of the semiconductor chip 2 and dissipates the heat to suppress transmission of the heat in the planar direction of the semiconductor chip 2. As a result, by suppressing the image capturing region 21 from becoming at a high temperature, the semiconductor chip 2 can suppress the occurrence of thermal shading.

Also, the image capturing region 21, and the peripheral circuit 26, which is an example of an electronic circuit, are provided on the same plane. The die-bonding material 4 is provided between the peripheral circuit 26 in the semiconductor chip 2 and the interposer substrate 3 having a larger area than the semiconductor chip 2.

The die-bonding material 4 transmits heat generated from the high density regions 23, 24, and 25 of the semiconductor chip 2 to the interposer substrate 3. As a result, the semiconductor device 1 can further improve the heat dissipation performance by causing the interposer substrate 3 having a large area to function as a heat dissipation plate.

Note that the structure of the semiconductor device according to the present disclosure is not limited to the structure illustrated in FIGS. 2A and 2B. The semiconductor device according to the present disclosure may have, for example, a structure illustrated in FIGS. 3A and 3B. FIG. 3A is an explanatory view illustrating a cross-sectional structure of a semiconductor device according to a modification example of the present disclosure. FIG. 3B is an exploded perspective view of the semiconductor device according to the modification example of the present disclosure.

As illustrated in FIG. 3A, in a semiconductor device 1a according to the modification example, a structure of a semiconductor chip 2a is different from that of the semiconductor chip 2 illustrated in FIG. 2A, and the structures of the other components are similar to those of the semiconductor device 1 illustrated in FIG. 2A. The semiconductor chip 2a includes a circuit layer 28 in which an electronic circuit is provided, and an image capturing layer 21a stacked on the circuit layer 28 and provided with an image capturing region.

In the circuit layer 28, the low density region 22 is provided along one of the four sides serving as the outer edge, and the high density regions 23, 24, and 25 are provided along the remaining three sides. In the case of the semiconductor chip 2a, the die-bonding material 4 is provided immediately below the high density regions 23, 24, and 25 along the high density regions 23, 24, and 25 between the circuit layer 28 and the interposer substrate 3.

As a result, the die-bonding material 4 absorbs heat generated from the high density regions 23, 24, and 25 from the lower side to enable the heat to be suppressed from being transmitted to the image capturing region provided on the circuit layer 28. Accordingly, the semiconductor device 1a can suppress the occurrence of thermal shading caused by heat generation in the high density regions 23, 24, and 25.

Also, in the semiconductor device 1a, since the die-bonding material 4 is provided between the semiconductor chip 2a and the interposer substrate 3 having a larger area than the semiconductor chip 2a, the interposer substrate 3 having a larger area can function as a heat dissipation plate to improve the heat dissipation performance.

[3. Arrangement Examples of High Density Region and Die-Bonding Material]

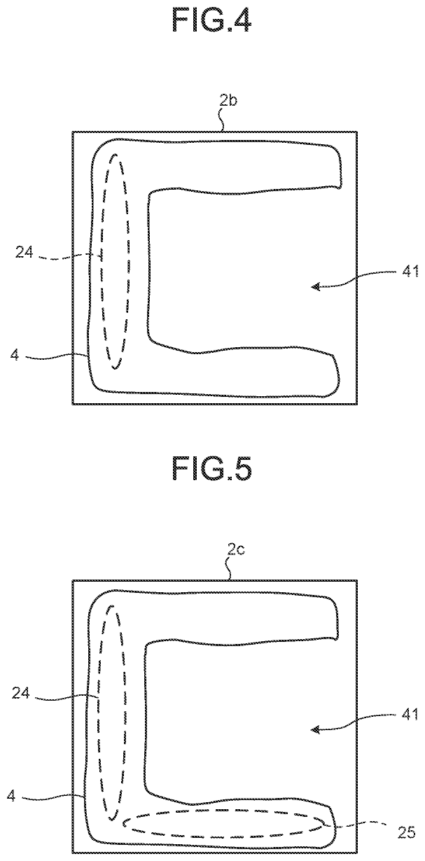

Next, arrangement examples of a high density region and a die-bonding material in the semiconductor device according to the present disclosure will be described. FIGS. 4 to 8 are explanatory views illustrating arrangement examples of a high density region and a die-bonding material in the semiconductor device according to the present disclosure.

As illustrated in FIG. 4, in a semiconductor chip 2b, the high density region 24 may be provided along one of the four sides serving as the outer edge. In this case, the die-bonding material 4 is formed along the high density region 24 in a C shape in which a part of an annular shape in a plan view is opened. The open portion 41 of the die-bonding material 4 is provided in a region having the lowest integration density of electronic circuits among regions in which the electronic circuits are provided along the four sides of the semiconductor chip 2b.

In the example illustrated in FIG. 4, the die-bonding material 4 is provided in a C shape in a plan view along a side provided with the high density region 24 and two sides continuing into the side provided with the high density region 24, and the open portion 41 is provided in a portion of a side opposed to the side provided with the high density region 24.

As a result, the die-bonding material 4 can efficiently use a temperature gradient generated in the semiconductor chip 2b to effectively dissipate heat generated from the high density region 24 to the outside of the semiconductor chip 2b. In addition, since the die-bonding material 4 also extends to the portions of the sides other than the side provided with the high density region 44, a region functioning as a heat dissipation plate can be expanded to the portions other than the high density region 44 to improve the heat dissipation performance.

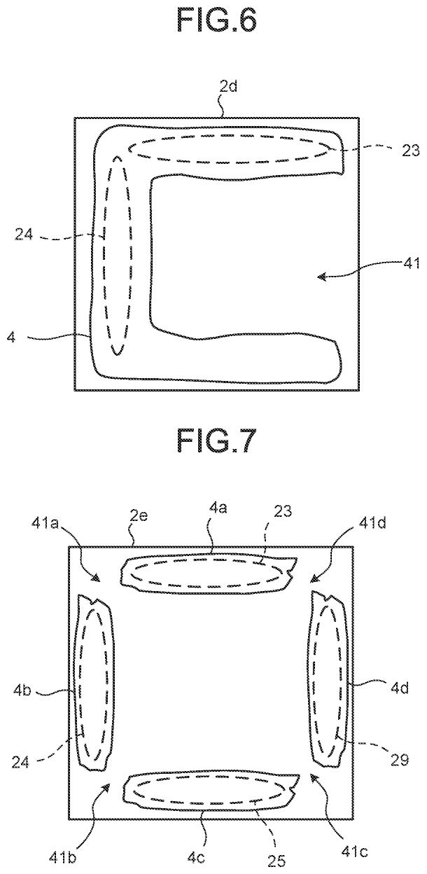

Also, as illustrated in FIG. 5, in a semiconductor chip 2c, the high density regions 24 and 25 may be provided along two adjacent continuous sides among the four sides serving as the outer edge. Further, as illustrated in FIG. 6, in a semiconductor chip 2d, the high density regions 23 and 24 may be provided along two adjacent continuous sides among the four sides serving as the outer edge.

In each of the cases, the die-bonding material 4 is formed along the high density regions 24 and 25 or the high density regions 23 and 24 in a C shape in which a part of an annular shape in a plan view is opened. The open portion 41 of the die-bonding material 4 is provided in a region having the lowest integration density of electronic circuits among regions in which the electronic circuits are provided along the four sides of the semiconductor chip 2b or 2c. As a result, the die-bonding material 4, as well as the die-bonding material 4 illustrated in FIG. 4, can improve the heat dissipation performance.

Further, as illustrated in FIG. 7, in a semiconductor chip 2e, high density regions 23, 24, 25, and 29 may be provided along the four sides serving as the outer edge. In this case, four die-bonding materials 4a, 4b, 4c, and 4d are annularly provided along the high density regions 23, 24, 25, and 29, and open portions 41a, 41b, 41c, and 41d are provided at the four corners of the semiconductor chip 2e, respectively.

As a result, in the high density regions 23, 24, 25, and 29, heat generated from the high density regions 23, 24, 25, and 29 is dissipated through the four open portions 41a, 41b, 41c, and 41d to the outside of the semiconductor device to enable the heat dissipation performance of the semiconductor device to be improved.

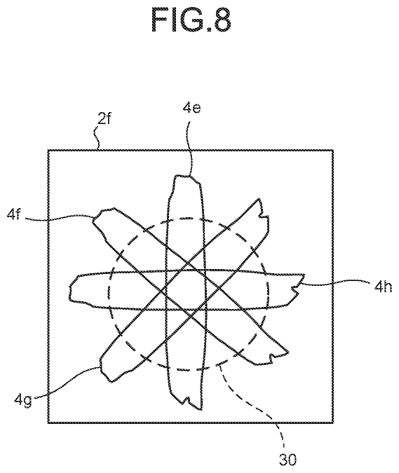

Further, as illustrated in FIG. 8, in a semiconductor chip 2f, a high density region 30 may be provided in the center region in a plan view. In this case, die-bonding materials 4e, 4f, 4g, and 4h are provided so as to radially extend from the center of the high density region 30 in a plan view toward the outer periphery. The die-bonding materials 4e, 4f, 4g, and 4h are also provided so that the end portions thereof extend further to the outside than the outer edge of the high density region 30.

As a result, the die-bonding materials 4e, 4f, 4g, and 4h can efficiently dissipate heat from the center portion of the semiconductor chip 2f in a plan view to the outside. In addition, since the die-bonding materials 4e, 4f, 4g, and 4h are radially provided to cause the area in contact with the outside air to increase, this can also contribute to improvement in the heat dissipation performance.

[4. Effects]

The semiconductor device 1 includes the semiconductor chip 2, the interposer substrate 3, and the die-bonding material 4 formed in a partially opened annular shape in a plan view. The semiconductor chip 2 includes the high density regions 23, 24, and 25 having high integration densities of electronic circuits and the low density region 22 having a low integration density. The semiconductor chip 2 is implemented on the interposer substrate 3. The die-bonding material 4 formed in a partially opened annular shape in a plan view is provided between the high density regions 23, 24, and 25 having high integration densities in the semiconductor chip 2 and the interposer substrate 3.

As a result, in the semiconductor device 1, heat generated from the high density regions 23, 24, and 25 is efficiently absorbed by the die-bonding material 4, and is effectively dissipated through the open portion 41 of the die-bonding material 4 to the outside of the semiconductor device 1, to enable the heat dissipation performance to be improved.

Also, in the semiconductor chip 2, the high density regions 23, 24, and 25 are provided along sides excluding at least one side which is the low density region 22 among the four sides serving as the outer edge. The die-bonding material 4 is provided along the high density regions 23, 24, and 25 in the semiconductor chip 2, and a part of the annular shape in a plan view is opened in a portion between the low density region 22 and the interposer substrate 3. As a result, the semiconductor device 1 can efficiently dissipate heat using a temperature gradient generated in the semiconductor chip 2.

Also, the semiconductor chip 2 is provided with the image capturing region 21 of the image sensor in the center region in a plan view surrounded by the high density regions 23, 24, and 25 and the low density region 22. The die-bonding material 4 is provided immediately below the high density regions 23, 24, and 25.

The die-bonding material 4 absorbs heat generated from the high density regions 23, 24, and 25 from the lower side of the semiconductor chip 2 and dissipates the heat to suppress transmission of the heat in the planar direction of the semiconductor chip 2. As a result, by suppressing the image capturing region 21 from becoming at a high temperature, the semiconductor device 1 can suppress the occurrence of thermal shading.

Also, the image capturing region 21 and the electronic circuit are provided on the same plane. The die-bonding material 4 is provided between the electronic circuit and the interposer substrate 3. As a result, the semiconductor device 1 can further improve the heat dissipation performance by causing the interposer substrate 3 to function as a heat dissipation plate.

Also, the semiconductor chip 2 includes the circuit layer 28 in which an electronic circuit is provided, and the image capturing layer 21a stacked on the circuit layer 28 and provided with an image capturing region. The die-bonding material 4 is provided between the circuit layer 28 and the interposer substrate 3.

The die-bonding material 4 absorbs heat generated from the high density regions 23, 24, and 25 from the lower side to enable the heat to be suppressed from being transmitted to the image capturing region provided on the circuit layer 28. Accordingly, the semiconductor device la can suppress the occurrence of thermal shading caused by heat generation in the high density regions 23, 24, and 25.

Also, a substrate on which the semiconductor chip 2 is implemented is the interposer substrate 3 generally having a larger area than the semiconductor chip 2. As a result, the semiconductor device 1 can improve the heat dissipation performance by causing the interposer substrate 3 having a large area to function as a heat dissipation plate.

Note that the effects described in the present specification are illustrative only and are not limited, and other effects may be provided.

Note that the present technique can also employ the following configuration.

(1)

A semiconductor device including:

a semiconductor chip which includes a region in which an integration density of an electronic circuit is high and a region in which the integration density is low;

a substrate on which the semiconductor chip is implemented; and

a die-bonding material which is provided between the region in which the integration density is high in the semiconductor chip and the substrate and which is formed in a partially opened annular shape in a plan view.

(2)

The semiconductor device according to (1), wherein,

in the semiconductor chip,

the region in which the integration density is high is provided along sides excluding at least one side which is the region in which the integration density is low among four sides serving as an outer edge, and

the die-bonding material is

provided along the region in which the integration density is high in the semiconductor chip, and a part of the annular shape of the die-bonding material in a plan view is opened in a portion between the region in which the integration density is low and the substrate.

(3)

The semiconductor device according to (2), wherein

the semiconductor chip is

provided with an image capturing region of an image sensor in a center region in a plan view surrounded by the region in which the integration density is high and the region in which the integration density is low, and

the die-bonding material is

provided immediately below the region in which the integration density is high.

(4)

The semiconductor device according to (3), wherein

the image capturing region and the electronic circuit are

provided on a same plane, and

the die-bonding material is

provided between the electronic circuit and the substrate.

(5)

The semiconductor device according to (3), wherein

the semiconductor chip includes

a circuit layer provided with the electronic circuit, and an image capturing layer stacked on the circuit layer and provided with the image capturing region, and

the die-bonding material is

provided between the circuit layer and the substrate.

(6)

The semiconductor device according to any one of (1) to (5), wherein

the substrate is

an interposer substrate.

### REFERENCE SIGNS LIST

1 SEMICONDUCTOR DEVICE

2 SEMICONDUCTOR CHIP

21 IMAGE CAPTURING REGION

22 LOW DENSITY REGION

23, 24, 25 HIGH DENSITY REGION

26, 27 PERIPHERAL CIRCUIT

28 CIRCUIT LAYER

3 INTERPOSER SUBSTRATE

4 DIE-BONDING MATERIAL

51 SUBSTRATE

52 BUMP

53 FRAME

1. A semiconductor device comprising:
a semiconductor chip which includes a region in which an integration density of an electronic circuit is high and a region in which the integration density is low;
a substrate on which the semiconductor chip is implemented; and
a die-bonding material which is provided between the region in which the integration density is high in the semiconductor chip and the substrate and which is formed in a partially opened annular shape in a plan view.

2. The semiconductor device according to claim 1, wherein,
in the semiconductor chip,
the region in which the integration density is high is provided along sides excluding at least one side which is the region in which the integration density is low among four sides serving as an outer edge, and
the die-bonding material is
provided along the region in which the integration density is high in the semiconductor chip, and a part of the annular shape of the die-bonding material in a plan view is opened in a portion between the region in which the integration density is low and the substrate.

3. The semiconductor device according to claim 2, wherein
the semiconductor chip is
provided with an image capturing region of an image sensor in a center region in a plan view surrounded by the region in which the integration density is high and the region in which the integration density is low, and
the die-bonding material is
provided immediately below the region in which the integration density is high.

4. The semiconductor device according to claim 3, wherein
the image capturing region and the electronic circuit are
provided on a same plane, and
the die-bonding material is
provided between the electronic circuit and the substrate.

5. The semiconductor device according to claim 3, wherein
the semiconductor chip includes
a circuit layer provided with the electronic circuit, and an image capturing layer stacked on the circuit layer and provided with the image capturing region, and
the die-bonding material is
provided between the circuit layer and the substrate.

6. The semiconductor device according to claim 1, wherein
the substrate is
an interposer substrate.
